(19) United States
(12) Patent Application Publication
(10) Pub. No.: US 2002/0086106 A1
(43) Pub. Date: Jul. 4, 2002

(54) Apparatus and method for thin film deposition

(76) Inventors: Chang-Soo Park, Seoul (KR); Sang-Gee Park, Seoul (KR); Jung-Hwan Choi, Seoul (KR); Bo-Shin Chung, Sungnam-shi (KR); Sang-Young Oh, Seoul (KR); Eung-Soo Lee, Gyeonggi-do (KR)

Correspondence Address: WILDMAN, HARROLD, ALLEN & DIXON, 225 WEST WACKER DRIVE, CHICAGO, IL, 60606, US

(21) Appl. No.: 10/039,357

(22) Filed: Nov. 7, 2001

(30) Foreign Application Priority Data
Nov. 7, 2000 (KR) 2000-65873

(51) Int. Cl. C23C 16/00

(52) U.S. Cl. 427/248.1; 118/715

(57) ABSTRACT

The apparatus for forming a thin film includes a reaction chamber having a top portion, a sidewall portion and a bottom portion; a gas injector penetrating the top portion and letting a source element pass therethrough; a distributor connected to the gas injector, wherein a plurality of injection holes are formed in the distributor and the source element is injected through the plurality of injection holes; and u substrate heating member positioned in a reaction space defined by the top, bottom and sidewall portions of the reaction chamber, and arranged below the distributor.

This application claims the benefit of Korean Patent Application No. 2000-65873, filed on Nov. 7,2000, under 35 U.S.C. §119, the entirety of which is hereby incorporated by reference.

### BACKROUND OF THE INVENTION

1. Field of the Invention

This invention relates to a semiconductor device manufacturing apparatus. More particularly, it relates to an apparatus and method for depositing a thin film.

2. Description of Related Art

The semiconductor devices, such as a memory IC (integrated circuit) and other logic elements, are generally fabricated by repeated depositing and patterning processes. When fabricating the semiconductor devices at the same condition, a thickness uniformity of the deposited thin film should be less than 5% in order to make all the semiconductor devices have an equal property. However, since the highly integrated and finely integrated circuits of semiconductor devices have recently been required, the thickness uniformity of thin film should be much less than 5% to improve the reliability of semiconductor devices.

In general, most deposition apparatus of thin film use a shower head as a reaction gas introducer, such that a chemical source gas is introduced into a reaction chamber to form the thin film. In order to obtain the thickness uniformity of the deposited thin film, the shower head is larger in size than a substrate in which the thin film is deposited, and a hole plate is employed in the shower head to uniformly disperse the chemical source gas. The hole plate generally includes a plurality of gas-dispersing holes dispersing the chemical source gas, and each gas-dispersing hole is divided into two parts—a first part having a relatively large diameter and a second part having a relatively small diameter. Therefore, the chemical source gas is broadly dispersed into the reaction chamber through the plurality of gas-dispersing holes.

However, when dispersing the chemical source gas into the reaction chamber, the chemical source gas is accumulated and remains in the gas-dispersing holes, thereby filling up the gas-dispersing holes. Additionally, since the dispersed chemical source gas delivers a by-product of reaction and a small amount of reactants, which are also accumulated in the gas-dispersing holes, upon the substrate, the by-product and reactants act as impurities in the thin film, thereby deteriorating the uniformity and composition of the thin film deposited on the substrate.

Furthermore, since the shower head is adjacent to a heater applying heat to the substrate, the shower head is easily heated by the heater and the chemical source gas is adversely affected by the heater. To overcome this problem, a cooling system is usually adopted in the shower head. Adopting the cooling system, however, makes the shower head's configuration more confusing. Also, since the shower heads have different structures and configurations depending on their manufacturers, it is difficult to substitute one thing for another. Accordingly to overcome this problem, it has been researched and developed to use an injector as a reaction gas introducer, as disclosed by U.S. Pat. No. 5,987,427, for example.

FIG. 1 shows a schematic sectional view illustrating a thin film deposition apparatus having an injector according to a conventional art. As shown in FIG. 1, the thin film deposition apparatus comprises a reaction chamber 10, a substrate heating member 20, a gas injector 30 and a substrate inlet/outlet 40. Also, the reaction chamber 10 can be divided into three parts—a sidewall portion 1, a bottom portion 12 and a top portion 13. In the meanwhile, the bottom portion 12 of the reaction chamber 10 includes a gas exhaust port that emits the air in the reaction chamber 10. The substrate heating member 20 is disposed in the center of the reaction chamber 10 and supported by a ram 21 that is mounted through the bottom portion 12 of the reaction chamber 10. A substrate or silicon wafer (not shown), where the thin film is deposited, is placed upon the substrate heating member 20 during the deposition processes, and the substrate heating member 20 including a heater applies heat to the substrate or silicon wafer. The substrate inlet/outlet 40 is positioned in the sidewall portion 11 of the action chamber 10, thereby taking the substrate or silicon wafer in or out of the reaction chamber l through this substrate inlet/outlet 40. The gas injector 30 injecting the chemical source gas is disposed around the substrate heating member 20. Although only one gas injector 30 is shown in FIG. 1, a plurality of the gas injectors 30 can surround the substrate heating member 20 depending on what kind of chemical source gas is applied or how many kinds of chemical source gases are injected.

Further referring to FIG. 1, the gas injector 30 penetrates the bottom portion 12 of the reaction chamber 10 and elongates along the sidewall portion 11 of reaction chamber 10. The top portion 13 of reaction chamber 10 has a dome shape. Since the gas injector 30 is headed for the dome-shaped top portion 13, the chemical source gas injected from the gas injector 30 rebounds from the top portion 13 of reaction chamber 10, or spreads alongside a surface of the dome-shaped top portion 13. Therefore, the chemical source gas is diffused inside the reaction chamber 10 so as to form the thin film on the substrate or silicon wafer. In this thin film deposition apparatus shown in FIG. 1, the chemical source gas is hardly affected by the heater installed in the substrate heating member 20.

In the above-described apparatus, the gas injector 30 can be plural around the heating member 20 and the substrate heating member 20 can be adjustable upward and downward in order to obtain uniform thin film and composition thereof. However, there are still some problems in the deposited thin film. Namely, the deposited t film has differences in thickness between a peripheral portion thereof adjacent to the gas injector 30 and a central portion thereof in the center of the substrate. Further in the above-described apparatus, the reaction chamber 10 requires an enough space therein in order to uniformly diffuse the injected and rebounded chemical source gas and to form a uniform thin film on the substrate, Therefore, the reaction chamber should have a large volume and a vacuum pump should be operated for a long Lime to evacuate a reaction space of reaction chamber 10. Additionally, a large amount of chemical source gas is required to form the thin film, thereby increasing the production cost.

In the meantime, when depositing the thin film using a conventional Chemical Vapor Deposition (CVD), it is impossible to obtain the thin film having an impurity density within a allowable limit and to make the thin film has a thickness of less than several nanometer. Therefore, a new technology to solve these problem has been research and introduced. For example, U.S. Pat. No. 4,058,430 discloses the Atomic Layer Deposition (ALD) method that is conventionally used for epitaxy on single crystals. According to the ALD method, two source elements are introduced into the reaction chamber respectively at a different time, thereby forming the thin film. In other words, the first source element is first introduced into the reaction chamber to form the single atomic layer on the substrate. Threreafter, residual substances after the deposition reaction are eliminated from the reaction chamber by the vacuum pump or using an inert gas. In the next step, the second source element is introduced into the reaction chamber to react with the first source element, resulting in the thin film on the substrate. In recent years, applying the ALD method to an apparatus and method for forming thin film semiconductor devices has been widely researched and developed.

The above-mentioned ALD method can be employed in both e apparatus having the shower head and the apparatus having the gas injector. U.S. Pat. No. 6,015,590 discloses another apparatus for the ALD method. According to the apparatus described in U.S. Pat. No. 6,015,590, the inflow duct is positioned below the substrate on which the thin film is formed using ALD method and the outflow duct is also positioned below the substrate opposite the inflow duct. Therefore, the source reactants arc scarcely diffused all over the reaction chamber. More specifically, the density of source reactants is higher around the inflow duct rather than around the outflow duct. From the result of this density disparity over the substrate, one portion of substrate adjacent to the inflow duct has a thicker thin film rather than the other portion of substrate adjacent to the outflow duct, thereby causing non-uniformity in thickness of the thin film. To overcome this problem, it is required to purge the reaction chamber for a sufficient time to evacuate the residual components from the reaction chamber. Therefore, it takes long time to form the thin film having the uniform thickness, and it is very difficult to obtain even thin film if the reaction chamber is not purged.

### SUMMARY OF THE INVENTION

Accordingly, the present invention is directed to an apparatus and method for depositing a thin film that substantially overcomes one or more of the problems due to limitations and disadvantages of the related art.

An object of the present invention is to provide an apparatus and method for forming a thin film that has uniform thickness and composition,

Another object of the present invention is to provide an apparatus and method for forming a super-thin film.

Additional features and advantages of the invention will be set forth in the description that follows, and in part will be apparent from the description, or may be learned by practice of the invention. The objectives and other advantages of the invention will be realized and attained by the structure particularly pointed out in the written description and claims hereof as well as the appended drawings.

In order to achieve die above object, an apparatus for forming a thin film includes a reaction chamber having a top portion, a sidewall portion and a bottom portion; a gas injector penetrating the top portion and letting a source element pass therethrough; a distributor connected to the gas injector, wherein a plurality of injection holes are formed in the distributor and the source element is injected through the plurality of injection holes; and a substrate heating member positioned in a reaction space defined by the top, bottom and sidewall portions of the reaction chamber, and arranged below the distributor.

The apparatus for forming the thin film further includes a ram that is mounted through the bottom portion of the reaction chamber to support the substrate heating member.

In the above-mentioned apparatus, the distributor includes a first portion having a cylindrical and a second portion shaped like a truncated cone, such that the plurality of injection holes are arranged at the side of the second portion of the distributor. Each injection hole includes a large diameter part accepting the source element and a small diameter part in which the velocity of source element increases, Here, the large diameter part has a large diameter rather than the small diameter part Furthermore, the substrate heating member is positioned at the center of the reaction space and the gas injector is disposed at the center of the top portion of the reaction chamber.

The above-mentioned apparatus can further include a plurality of distributors that are classified into a first distributor at the center of the top portion and a second distributor around the first distributer in the top portion so as to inject the source element tat includes a primary reactant element and a secondary reactant element. Here, the primary reactant element passes through the first distributor arranged at the center of the top portion and the secondary reactant element passes through the second distributor arranged around the first distributor. Furthermore, an axis of the second distributor forms an angle of about 90 degrees or less than 90 degrees with an axis of the first distributor when the first and second distributors are disposed at the top portion of the reaction chamber. The secondary reactant element is selected from a group consisting of ammonia (NH₃), hydrazine (N₂H₄), water vapor (H₂O), oxygen (O₂) and ozone (O₃).

In the present invention, the number of and the size of the injection holes vary depending on the reaction space of the reaction chamber. The top portion of the reaction chamber has a dome shape, and the substrate heating member includes both a heating element and an electric power source supply as one body.

To achieve these and other advantages and in accordance with the purpose of the present invention, as embodied and broadly described, in a method for forming a thin film in a deposition apparatus that has a reaction chamber having a reaction space therein, a substrate heating member disposed in the reaction space, a gas injector in a top portion of the reaction chamber, and a distributor connected to the gas injector, the method includes the steps of: streaming a chemical source gas through the gas injector; injecting the chemical source gas into the reaction space through the distributor that having a plurality of injection holes; and reacting the chemical source gas, whereby the thin film is formed upon a substrate that is disposed on the substrate heating member.

In the above-mentioned method, the distributor includes a first portion having a cylindrical and a second portion shaped like a truncated cone. Further, the plurality of injection holes are arranged at the side of the second portion of the distributor. Each injection hole includes a large diameter part accepting the chemical source gas and a small diameter part in which the velocity of chemical source gas increases.

It is to be understood that both the foregoing general description and the following detailed description are exemplary and explanatory and are intended to provide further explanation of the invention as claimed.

The accompanying drawings are included to provide a further understanding of the invention and are incorporated in and constitute a part of this specification, illustrate one embodiment of the invention and together with the description serve to explain the principles of the invention.

### BRIEF DESCRIPTION OF THE DRAWINGS

The accompanying drawings, which are included to provide a further understanding of the invention and are incorporated in and constitute a part of this application, illustrate embodiment of the invention and together with the description serve to explain the principle of the invention.

In the drawings:

FIG. 1 shows a schematic sectional view illustrating a thin film deposition apparatus having an injector according to a conventional art;

FIG. 2 shows a schematic sectional view illustrating a thin film deposition apparatus having a distributor according to a present invention;

FIG. 3A is a side view of the distributor according to the present invention;

FIG. 3B is a bottom plan view of the distributor according the present invention;

FIG. 4 is a section view showing an injection hole of the distributor according to the present invention;

FIG. 5A is a graph showing a thickness of aluminum oxide (Al₂O₃) thin films formed by an inventive apparatus of the present invention;

FIG. 5B is a graph showing thickness uniformity of aluminum oxide (Al₂O₃) thin films formed by the inventive apparatus of the present invention; and

FIGS. 6A and 6B are graphs attained using Rutherford Backscattering Spectroscopy (RBS) measurement on aluminum oxide (Al₂O₃) thin films formed by the inventive apparatus of the present invention.

### DETAILED DESCRIPTION OF ILLUSTRATED EMBODIMENTS

Reference will now be made in detail to illustrated embodiment of the present invention, examples of which are shown in the accompanying drawings. Wherever possible, the same reference numbers will be used throughout the drawings to refer to the same or like parts.

In the present invention, a distributor having a plurality of injection holes is connected to an injector such that a chemical source gas is spouted through the plurality of injection holes. The chemical source gas from the gas injector is thus evenly diffused in the reaction chamber, thereby forming a uniform thin film upon a substrate. Further, since the Atomic Layer Deposition (ALD) method is employed in the present invention to form the thin film, a super-thin film is obtained with a uniform composition. The detailed explanation will be followed hereinafter.

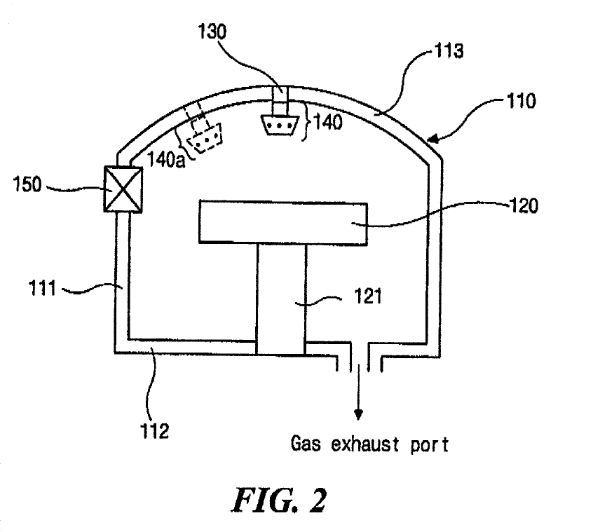

FIG. 2 shows a schematic sectional view illustrating a thin film deposition apparatus having a distributor according to a present invention. As shown in FIG. 2, the thin film deposition apparatus comprises a reaction chamber 110, a substrate heating member 120, a gas injector 130 and a substrate inlet/outlet 140. Also, the reaction chamber 110 can be divided into three parts—a sidewall portion 111, a bottom portion 112 and a top portion 113. These sidewall 111, bottom 112 and top 113 portions define a reaction space inside the reaction chamber 110. In the meanwhile, the bottom portion 112 of the reaction chamber 110 includes a gas exhaust port that emits the air in the reaction chamber 110. The substrata heating member 120 is disposed in the central reaction space of the reaction chamber 10 and supported by a ram 121 that is mounted through the bottom portion 112 of the reaction chamber 110. A substrate or silicon wafer (not shown), where the thin film is deposited, is placed upon the substrate heating member 120 during the deposition processes, and the substrate heating member 120 including a heater applies heat to the substrate or silicon wafer thereon. The substrate inlet/outlet 150 is positioned in the sidewall portion 111 of the reaction chamber 10, thereby taking the substrate or silicon wafer in or out of the reaction chamber 10 through this substrate inlet/outlet 150. Although FIG. 2 shows only one substrate inlet/outlet 150, another substrate inlet/outlet can be formed in the sidewall portion 111 opposite to the fit one, thereby acting as an entrance or exit for the substrate respectively.

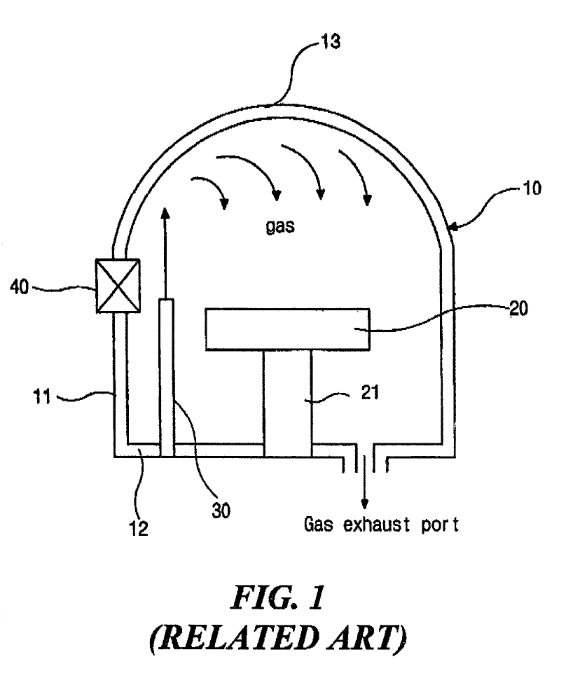

Further in FIG. 2, the gas injector 130 injecting the chemical source gas is disposed at the center of the top portion 113. Although only one gas injector 130 is shown in FIG. 1, a plurality of the gas injectors 130 can be disposed in the top portion 113 of the reaction chamber 110, preferably in the central part of the top portion 113. The top portion 113 has a dome shape as shown in FIG. 2, but it can have a planar shape. The gas injector 130 penetrates the top portion 112 of the reaction chamber 110, a distributor 140 having a plurality; of injection holes is connected to the end of the gas injector 130 to distribute the chemical source gas into the reaction space of the reaction chamber 110.

In the construction of the present invention described above, the substrate heating member 120 includes both a heating element and an electric power source supply as one body. Thus, the reaction space of the reaction chamber 110 increases. Furthermore, since the gas injector 130 penetrates and is positioned in the center of the top portion 113, the reaction space of the reaction chamber 110 increases, in contrast to the conventional art.

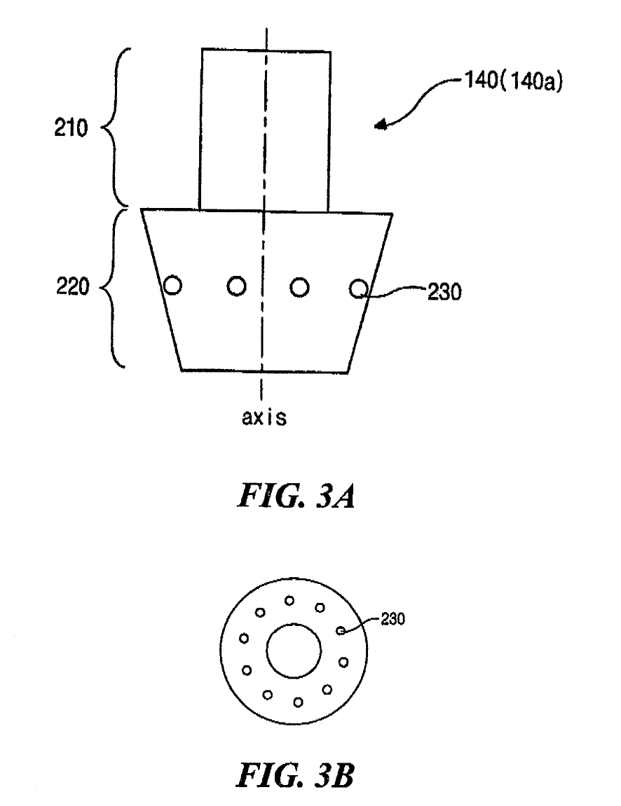

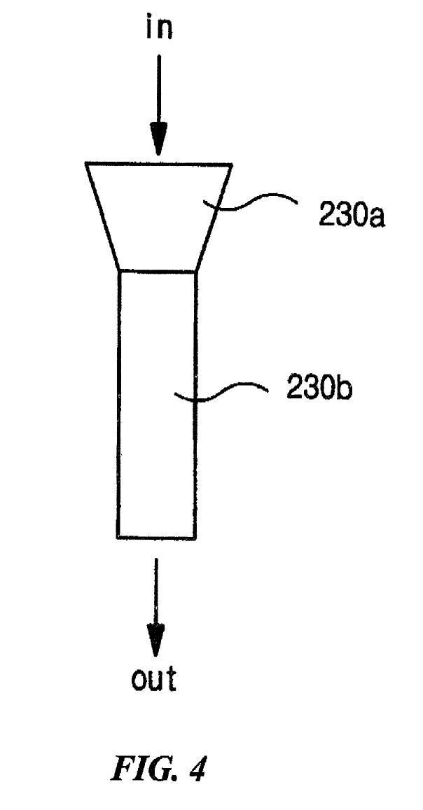

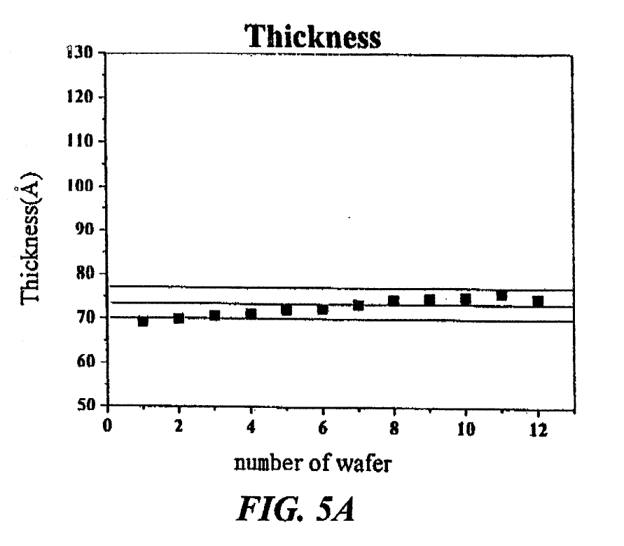

Now, the distributor 140 will be explained referring to FIGS. 3A-3B and 4. FIG. 3A is a side view of the distributor 140 according to the present invention; FIG. 3B is a bottom plan view of the distributor 140 according the present invention; and FIG. 4 is a section view showing an injection hole of the distributor according to the present invention.

Referring to FIGS. 3A and 3B, the distributor 140 is divided into a first portion 210 and a second portion 220. The first portion 210 has a cylindrical shape while the second portion 220 is shaped like a truncated cone. The top area of the second portion 220 is larger than the bottom area thereof, and thus the second portion 220 has an inverted truncated cone shape. At the side of the second portion 220, a plurality of injection holes 230 are formed such that the chemical source gas from the gas injector 130 (in FIG. 2) is injected through these injection holes 230 and spreads all over tee reaction space of the reaction chamber 110 (in FIG. 2). Since the plurality of injection holes 230 are disposed in the side of the second portion 220, the chemical source gas is prevented from being directly injected to the substrate. The number of injection holes and the diameter thereof depends on the volume of reaction space. Although the volume of reaction space is large, the number of injection holes and the diameter thereof can decrease depending on what kind of the chemical source gas is. Further in the present invention, the top area of the first portion 210 has substantially a bolt shape having a plurality of screw threads in order to be fixed to the gas injector 130 of FIG. 2.

FIG. 4 is a section view showing an injection hole 230 of the distributor 140 according to the present invention, In FIG. 4, the injection hole 230 is divided into two parts—a large diameter part 230a and a small diameter part 230b. The large diameter part 230a accepts the chemical source gas such that the chemical source gas passes through the small diameter part 230b. Since the large diameter part 230a has a larger diameter rather than the small diameter part 230b, the velocity of the chemical source gas increases due to the Venturi Effect after passing through the injection hole 230. Therefore, the chemical source gas injected through the injection holes 230 is uniformly spread over the reaction space of the reaction chamber 110 of FIG. 2.

As mentioned before, a plurality of distributors can be installed in the top portion 113 of the reaction chamber 110 depending on the chemical source gas. At this time, the plural distributors are advisably arranged around the center of the top portion 113 which corresponds to the substrate. Further, each distributor is coupled up to each gas injector.

The source elements such like the chemical source gas for forming the thin film are classified into primary reactant element and secondary reactant element. When injecting the primary and secondary reactant elements respectively through the distributors, the distributor for the primary reactant element (i.e., first distributor 140 of FIG. 2) is substantially arranged at the center of the top portion 113, and the distributor for the secondary reactant element (i.e., second distributor 140a of FIG. 2) is arranged around the distributor for the primary reactant element. Especially, the axis of the second distributor (in FIG. 3) forms an angle of about 90 degrees or less than 90 degrees with the axis of the first distributor. Meanwhile, when forming an oxidized thin film upon the substrate, H₂O, O₂ and/or O₃ are used as secondary reactant elements. In addition, when forming a nitride thin film upon the substrate, ammonia (NH₃) and/or hydrazine (N₂H₄) are used as secondary reactant elements.

In the thin film deposition apparatus according to the present invention, since the distributor has a small number of injection holes and has a small size rather than the shower head device, the impurity products and particles are hardly produced in the distributor, thereby decreasing the inferiority of the thin film.

In addition, when using the shower head device for forming the thin film, a lot of source elements are required because the shower head is larger in size than the substrate and has more injection holes than the distributor, However, the deposition apparatus according to the present invention needs less source elements than the conventional apparatus having the shower head device because the distributor has a fewer number of injection holes and a small size. Furthermore, the deposition apparatus according to the present invention can be adopted in the aforementioned ALD method, and thus the thin film having a minute thickness and a uniform composition is obtained.

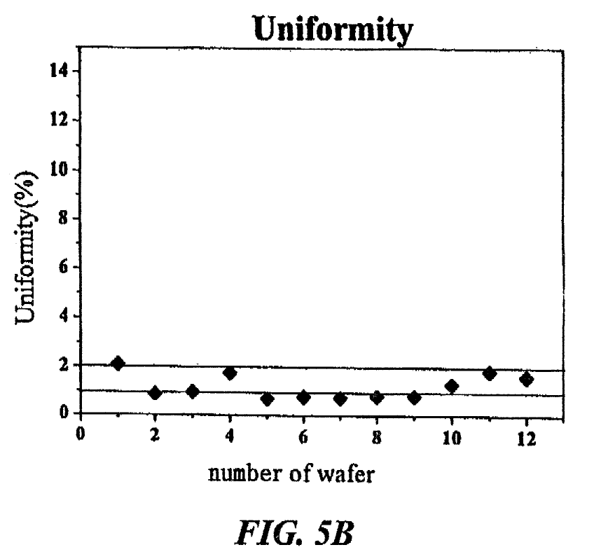

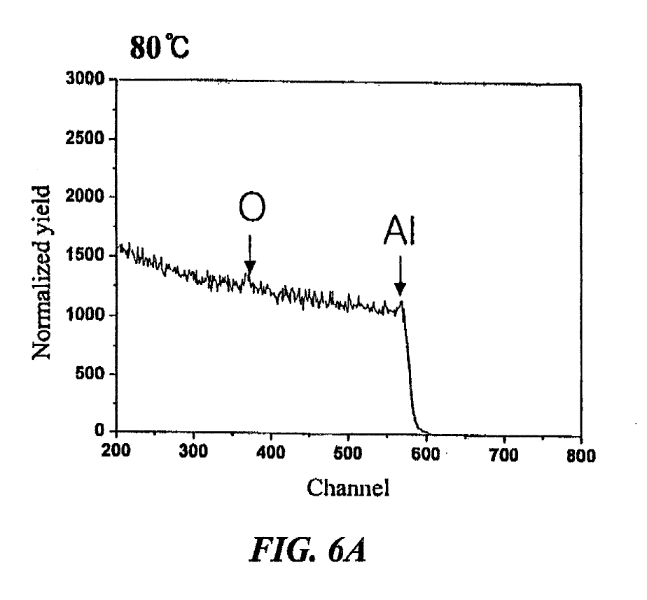

FIG. 5A is a graph showing a thickness of aluminum oxide (Al₂O₃) thin films formed by an inventive apparatus of the present invention, and FIG. 5B is a graph showing thickness uniformity of aluminum oxide (Al₂O₃) thin films formed by the inventive apparatus of the present invention. Before testing the thickness and thickness uniformity of the aluminum oxide (Al₂O₃) thin films, trimethyialzluninum (Al(CH₃)₃) and water vapor (H₂O) was used as source elements for forming the aluminum oxide (Al₂O₃) thin film. Additionally, the aluminum oxide (Al₂O₃) thin films were formed upon a dozen of silicon wafers, respectively, using the ALD) method. At this time of deposition, the temperature of the silicon wafers was 200 Celsius degrees. Since the thickness of aluminum oxide (Al₂O₃) thin film is generally less than 100 angstroms in the semiconductor devices, the aluminum oxide (Al₂O₃) then film for this experiment was formed within 100 angstroms.

Each point in the graph of FIG. 5A represents the average value of the thicknesses of the thin film which are measured in 25 points upon each substrate. As shown in FIG. 5A, the thicknesses of the thin films range from 70 angstroms to 80 angstroms.

FIG. 5B shows the thickness uniformity of the thin films formed on the substrates numbered 1 to 12. The thickness uniformity is calculated by the equation as follows:

[(tₘₐₓ−tₘᵢₙ)/(2×Tₐᵥᵣ)]×100

In the above equation, Tₐᵥᵣ is the average value of the thin film thicknesses which are measured in 25 points upon each substrate, tₘₐₓ is the maximum thickness of each thin film formed on each substrate, and tell is the minimum thickness of each thin film formed on each substrate. Accordingly as shown in FIG. 5B, the thickness uniformity of the deposited thin films ranges within 2 percents (%).

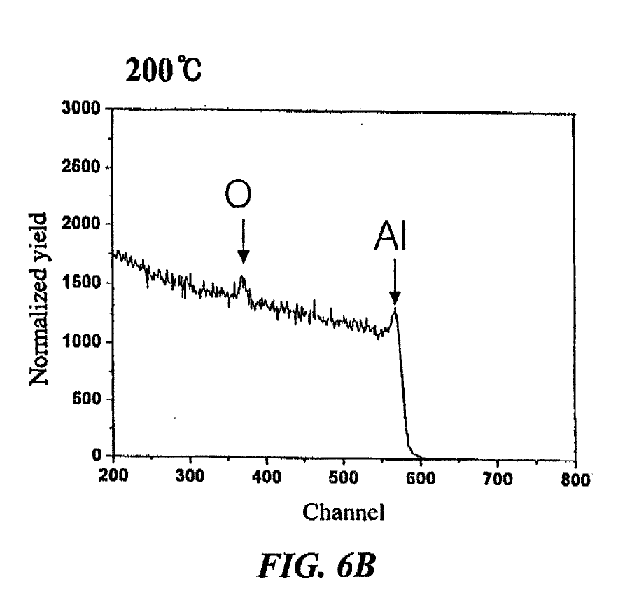

FIGS. 6A and 6B are graphs attained using Rutherford Backscattering Spectroscopy (RBS) measurement on aluminum oxide (Al₂O₃) thin films formed by the inventive apparatus of the present invention. The aluminum oxide (Al₂O₃) thin film for the measurement shown in FIG. 6A is formed upon the substrate at a temperature of 80 Celsius degrees while the thin film shown in FIG. 6B is formed at a temperature of 200 Celsius degrees.

When the aluminum oxide (Al₂O₃) thin film is formed using the conventional apparatus, the source element such as trimethylaluminum (Al(CH₃)₃) is not completely decomposited, thereby causing the generation of impurities such as carbon. Further to overcome this problem in the conventional art, a thermal treatment at a high temperature is required to obtain a proper aluminum oxide composition. However, when forming the aluminum oxide (Al₂O₃) thin film according to the present invention, the impurities do not exist in the aluminum oxide (Al₂O₃) thin film, and the atomic ratio of aluminum oxide (Al:O) results in 2.2:2.9 (i.e., Al_{2.2}O_{2.8}) that is approximately close to the ideal composition ratio 2:3 (i.e., Al₂O₃). In addition, the thermal treatment is not required in the present invention.

Accordingly within the principles of the present invention, since the distributor injects the source elements through the injection holes therein, the thin film has the uniform thickness upon the substrate. Also, since the Atomic Layer Deposition (AMD) method is adopted in the present invention, the thin film deposited on the substrate has the uniform composition without the impurities.

It will be apparent to those skilled in the art that various modifications and variations can be made in the capacitor and the manufacturing method thereof of the present invention without departing from the spirit or scope of the inventions. Thus, it is intended that the present invention cover the modifications and variations of this invention provided they come within the scope of the appended claims and their equivalents.

What is claimed is:

1. An apparatus for forming a thin film, comprising:
a reaction chamber having a top portion, a sidewall portion and a bottom portion;
a gas injector penetrating the top portion and letting a source element pass therethrough;
a distributor connected to the gas injector, wherein a plurality of injection holes are formed in the distributor and the source element is injected through the plurality of injection holes; and
a substrate beating member positioned in a reaction space defined by the top, bottom and sidewall portions of the reaction chamber, and arranged below the distributor.

2. The apparatus of claim 1, further comprising a ram that is mounted through the bottom portion of the reaction chamber to support the substrate heating member.

3. The apparatus of claim 1, wherein the distributor includes a first portion having a cylindrical and a second portion shaped like a truncated cone.

4. The apparatus of claim 3, wherein the plurality of injection holes are arranged at the side of the second portion of the distributor.

5. The apparatus of claim 4, wherein each injection hole includes a large diameter part accepting the source element and a small diameter part in which the velocity of source element increases.

6. The apparatus of claim 4, wherein the large diameter part has a large diameter rater than the small diameter part.

7. The apparatus of claim 1, wherein the substrate heating member is positioned at the center of the reaction space and the gas injector is disposed at the center of the top portion of the reaction chamber.

8. The apparatus of claim 1, further comprising a plurality of distributors that are classified into a first distributor at the center of the top portion and a second distributor around the first distributor in de top portion so as to inject the source element.

9. The apparatus of claim 8, wherein the source element includes a primary reactant element and a secondary reactant element.

10. The apparatus of claim 9, wherein the primary reactant element passes through the first distributor arranged at the center of the top portion and the secondary reactant element passes through the second distributor arranged around the first distributor.

11. The apparatus of claim 10, wherein an axis of the second distributor forms an angle of about 90 degrees with an axis of the first distributor when the first and second distributors are disposed at the top portion of the reaction chamber.

12. The apparatus of claim 10, wherein an axis of the second distributor forms an angle of less than 90 degrees with an axis of the first distributor when the first and second distributors are disposed at the top portion of the reaction chamber.

13. The apparatus of claim 10, wherein the secondary reactant element is selected from a group consisting of ammonia (NH₃), hydrazine (N₂H₄), water vapor (H₂O), oxygen (O₂) and ozone (O₃).

14. The apparatus of claim 1, wherein the number of and the size of the injection holes vary depending on the reaction space of the reaction chamber.

15. The apparatus of claim 1, wherein the top portion of the reaction chamber has a dome shape.

16. The apparatus of claim 1, wherein the substrate heating member includes both a heating element and an electric power source supply as one body.

17. A method for forming a thin film in a deposition apparatus that has a reaction chamber having a reaction space therein, a substrate heating member disposed in the reaction space, a gas injector in a top portion of the reaction chamber, and a distributor connected to the gas injector, the method comprising the steps of:
streaming a chemical source gas through die gas injector;
injecting the chemical source gas into the reaction space through the distributor that having a plurality of injection holes; and
reacting the chemical source gas, whereby the thin film is formed upon a substrate that is disposed on the substrate heating member.

18. The method of claim 17, wherein the distributor includes a first portion having a cylindrical and a second portion shaped like a truncated cone.

19. The apparatus of claim 18, wherein the plurality of injection holes are arranged at the side of the second portion of the distributor.

20. The apparatus of claim 19, wherein each injection hole includes a large diameter part accepting the chemical source gas and a small diameter part in which the velocity of chemical source gas increases.
